(19) United States
(12) Patent Application Publication
(10) Pub. No.: US 2006/0232941 A1
(43) Pub. Date: Oct. 19, 2006

(54) Heat sink and the method for making the same

(75) Inventors: Chi-Wei Huang, Pingdong Hsien (TW); Feng-Kuan Lee, Sanchong City (TW); Yung-Cheng Lu, Zhongli City (TW)

Correspondence Address: PATENTTM.US, P. O. BOX 82788, PORTLAND, OR, 97282-0788, US

(73) Assignee: COOLER MASTER CO., LTD.

(21) Appl. No.: 11/108,920

(22) Filed: Apr. 18, 2005

(51) Int. Cl. H05K 7/20

(52) U.S. Cl. 361/709

(57) ABSTRACT

A heat sink includes multiple heat dissipating fins securely connected to each other and each heat dissipating fin having a board, a through hole defined through the board, a receiving space formed on an attachment on a side face of the board to communicate with the through hole, an adhesive heat conductive agent received in the receiving space and a heat conductive tube extending through aligned through holes of the heat dissipating fins, the adhesive heat conductive agent is so arranged in the receiving space that the adhesive heat conductive agent covers an outer periphery of the heat conductive tube and fills a gap between the heat conductive tube and the heat dissipating fins, thus engagement between the heat conductive tube and the heat dissipating fins is secured after the adhesive heat conductive agent has cooled and hardened.

### BACKGROUND OF THE INVENTION

1. Field of the Invention

The present invention relates to a heat sink, and more particularly to a heat sink making method to allow a heat conductive tube to securely engage with the fins of the heat sink.

2. Description of Related Art

Due to the fast operational speed of electronic appliances, heat dissipation becomes the major problem to maintain the electronic appliances to work normally. Numerous devices are developed to the market to rapidly dissipate the heat from the electronic appliances, however, some of them still suffer from different drawbacks. The most common heat dissipating device is composed of a fan assembly to use air flow to take away the heat resulted from the high rotational speed of the electronic appliance e.g. CPU. Another heat dissipating device is to use a fan assembly and a heat sink having multiple heat dissipating fins formed on the heat sink. Thus when the heat sink receives heat from the electronic appliance, the air flow from the fan assembly is able to effectively take the heat away from the heat sink so as to lower the electronic appliance's temperature.

With reference to FIGS. 15 and 16, a different heat dissipating device is to use a combination of heat sink and a heat conductive tube (1). The heat sink has multiple heat dissipating fins (2) securely connected to each other and respectively having a through hole (3) defined through the heat dissipating fin (2) and a cutout (5) defined in each of the heat dissipating fins (2) to communicate with the through hole (3). After the heat conductive tube (1) is inserted into the through hole (3) of the heat sink, a metal wire (6), as shown in FIG. 16, is then inserted into the cutouts (5) of the heat sink. Thereafter, a heating process is employed to melt the metal wire (6) to allow the molten metal to flow allover the heat conductive tube (1) so as to securely connect the heat conductive tube (1) to the heat sink. However, the heating process to melt the metal wire (6) so as to secure the engagement between the heat conductive tube (1) and the heat sink will damage the heat conductive tube (1) if the material of the heat conductive tube (1) is the same as that of the metal wire (6), or at least has a similar melting point.

Yet another heat dissipating device as shown in FIG. 17 is also composed of a heat sink and a heat conductive tube. The difference between this and the previously described one is that an adhesive agent is employed instead of the metal wire. The adhesive agent flows into cutouts (43) of heat dissipating fins (41) to fill a gap between the heat dissipating fins (41) and a heat conductive tube (45) after being inserted into through holes (44) of each of the heat dissipating fins (41) so as to securely connect the heat sink to the heat conductive tube (45). Using the adhesive agent does prevent the heat conductive tube (45) from being damaged by high temperature in that there is no heating process involved to engage the heat conductive tube (45) with the heat sink. However, the cutout (43) of each of the heat dissipating fins (41) has a dimension so small that after the heat dissipating fins (41) are connected to one another, there is no control of the flowing pattern of the adhesive agent. That is, whether the adhesive agent fills each gap between the heat conductive tube (45) and each of the heat dissipating fins (41) is uncertain so that the integrity of the heat dissipating device is not secured.

To overcome the shortcomings, the present invention tends to provide an improved heat sink to mitigate the aforementioned problems.

### SUMMARY OF THE INVENTION

The primary objective of the present invention is to provide a heat sink to ensure that engagement between the heat dissipating fins and the heat conductive tube is secured.

Another objective of the present invention is to provide a method for making a heat sink.

In order to accomplish the aforementioned objective, the heat sink of the present invention includes multiple heat dissipating fins each having a through hole defined through the heat dissipating fin and a receiving space defined in a periphery defining the through hole to communicate with the through hole such that an adhesive agent is able to be temporarily received in the receiving space of each of the heat dissipating fins. After the insertion of the heat conductive tube into the through holes of the heat dissipating fins and inverting the combination of the heat dissipating fins and the heat conductive tube, a heating process is employed to melt the adhesive agent. The adhesive agent then flows to fill gaps between the heat conductive tube and the heat dissipating fins. Thereafter, a cooling process is employed to cool and harden the adhesive agent and thus the engagement between the heat conductive tube and the heat dissipating fins is secured.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a heat dissipating fin constructed in accordance with the present invention;

FIG. 2 is a schematic view in partial cross section to show the combination of the heat dissipating fins and the heat conductive tube;

FIG. 3 is a schematic view in partial cross section to show a reversing process is employed to allow the adhesive agent to flow over the heat conductive tube so as to fill gaps between the heat dissipating fins and the heat conductive tube;

FIG. 4 is a perspective view of a second embodiment of a heat dissipating fin constructed in accordance with the present invention;

FIG. 5 is a cross sectional view of the heat dissipating fin in FIG. 4;

FIG. 6 is a schematic view in partial cross section to show that a heat conductive tube is to combine with the heat dissipating fins;

FIG. 7 is a schematic view in partial cross section showing a inverting process is employed to the heat conductive tube and the heat dissipating fins;

FIG. 8 is a side plan view of a third embodiment of the heat dissipating fin constructed in accordance with the present invention;

FIG. 9 is a cross sectional view of the heat dissipating fin in FIG. 8;

FIG. 10 is a schematic view in partial cross section showing a heat conductive tube is inserted into the heat sink having therein an adhesive agent;

FIG. 11 is a schematic view showing that a reversing process and a heating process are employed to allow the adhesive agent to flow and cover the heat conductive tube;

FIG. 12 is a perspective view of a fourth embodiment of the heat dissipating fin constructed in accordance with the present invention;

FIG. 13 is a schematic view showing that an adhesive agent is received in the receiving space of the fourth embodiment;

FIG. 14 is a schematic view showing that a reversing process is employed to the combination of the heat sink and the heat conductive tube;

FIG. 15 is a perspective view of a conventional heat sink having therein a heat conductive tube;

FIG. 16 is an enlarged perspective view showing the engagement between the heat sink and heat conductive tube of FIG. 15; and

FIG. 17 is a perspective view of a different conventional heat sink having therein a heat conductive tube.

### DETAILED DESCRIPTION OF THE PREFERRED EMBODIMENT

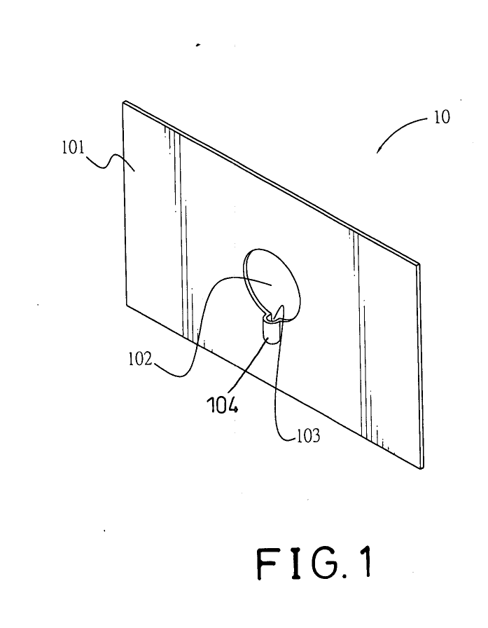

With reference to FIG. 1, a heat dissipating fin (10) constructed in accordance with the present invention includes a board (101) with a through hole (102) defined through the board (101) and a receiving space defined in a periphery defining the through hole (102). The receiving space is formed by a protrusion (104) extending from a side face of the board (101) and having therein an indentation (103) defined in the protrusion (104) to communicate with the through hole (102).

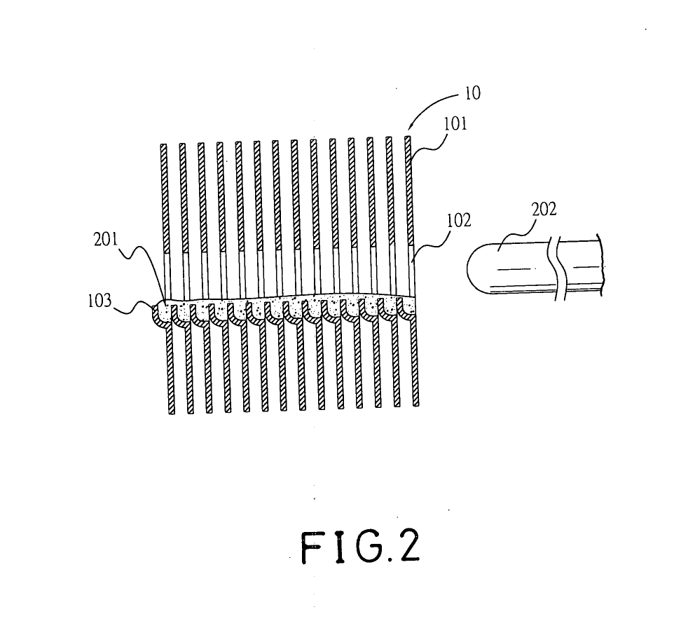

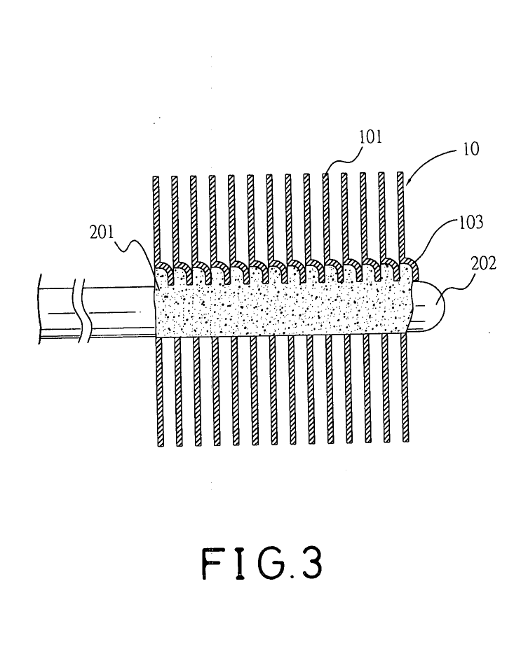

With reference to FIGS. 2 and 3, it is noted that the heat sink of the present invention further has a heat conductive tube (202) corresponding to the through hole (102) of the heat dissipating fin (10). When the heat sink of the present invention is to be assembled, multiple heat dissipating fins (10) are joined together to allow the through holes (102) of the heat dissipating fins (10) to align. Then an adhesive heat conductive agent (201) made of a material such as gold, silver or tin or the combination thereof is injected into the aligned through holes (102) to be received in each of the indentations (104) before the heat conductive tube (202) is extended into the aligned through holes (102) of the heat dissipating fins (10). With the extension of the heat conductive tube (202) into the through holes (102) of the heat dissipating fins (10), the combination of the heat conductive tube (202) and the heat dissipating fins (10) having therein the adhesive heat conductive agent (201) is first placed up side down. Then a heating process is employed to melt the adhesive heat conductive agent (201) to allow the adhesive heat conductive agent (201) to flow out of the indentations (104) and eventually fill a gap between the heat dissipating fins (10) and the heat conductive tube (202). Thereafter, when the adhesive heat conductive agent (201) has cooled and hardened, the heat conductive tube (202) is securely connected to the heat dissipating fins (10).

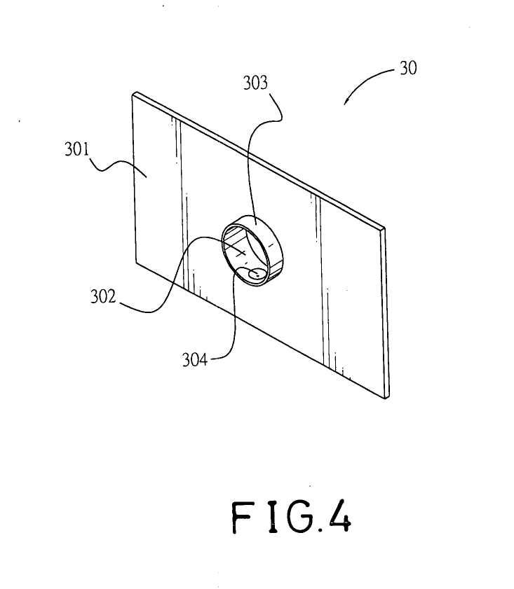

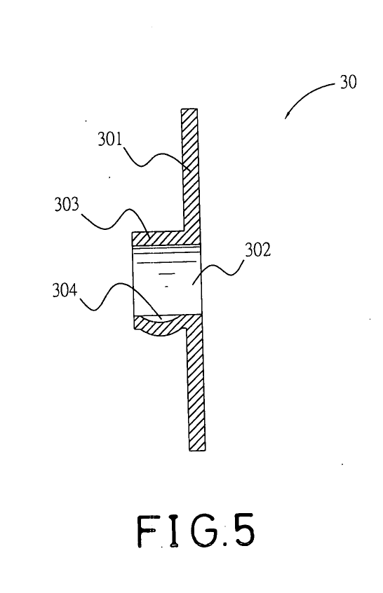

With reference to FIGS. 4 and 5, the heat dissipating fin (30) constructed in accordance with the present invention includes a board (301), a through hole (302) defined through the board (301) and a ring (303) formed on and extending from a periphery defining the through hole (302). The receiving space in this embodiment is defined as a recess (304) defined in an inner periphery of the ring (303).

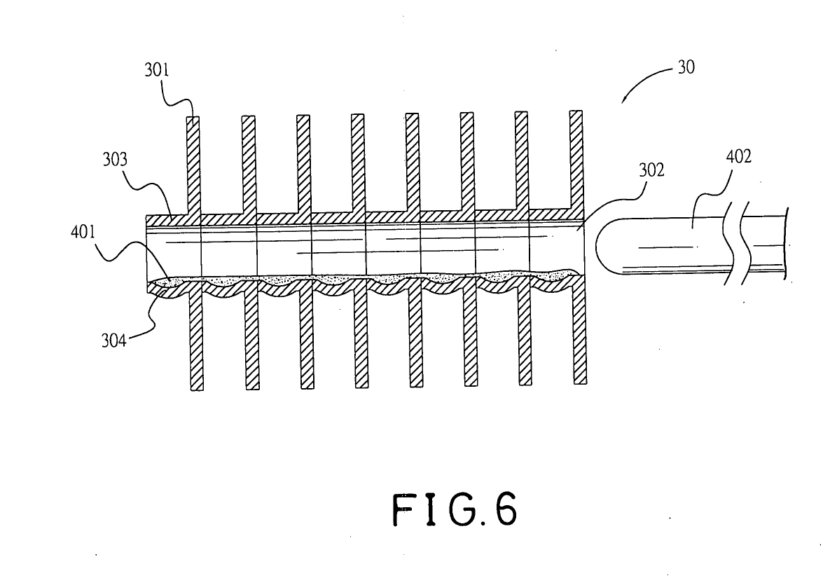

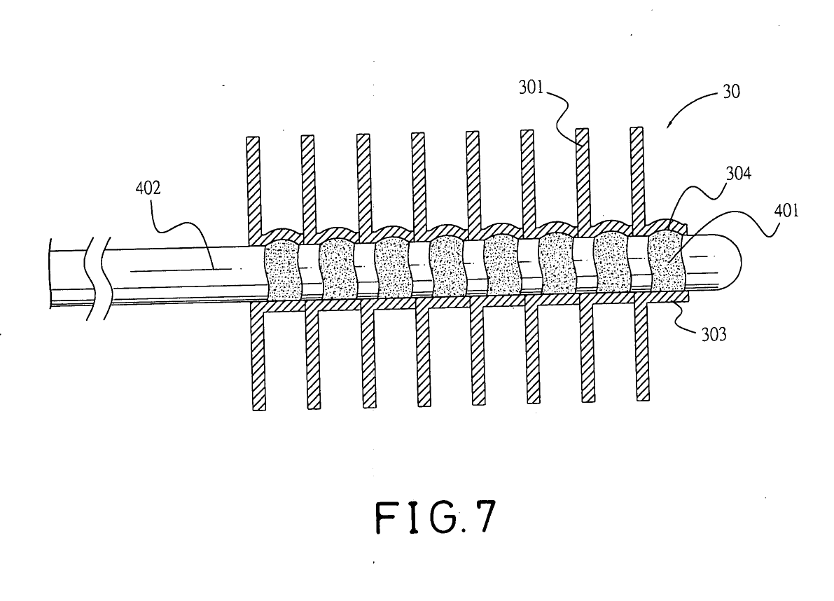

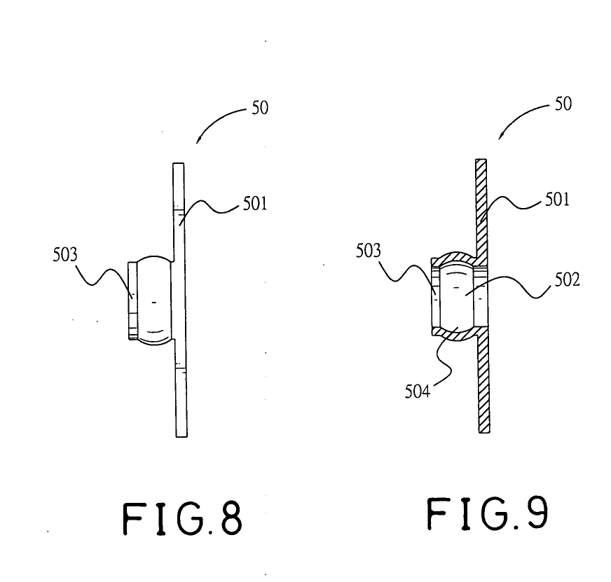

With reference to FIGS. 6 and 7, when the heat sink of the present invention is to be assembled, multiple heat dissipating fins (30) are joined together to allow the through holes (302) of the heat dissipating fins (30) to align. Then an adhesive heat conductive agent (401) made of a material such as gold, silver or tin or the combination thereof is injected into the aligned through holes (302) to be received in each of the recesses (304) before a heat conductive tube (402) is extended into the aligned through holes (302) of the heat dissipating fins (30). With the extension of the heat conductive tube (402) into the through holes (302) of the heat dissipating fins (30), the combination of the heat conductive tube (402) and the heat dissipating fins (30) having therein the adhesive heat conductive agent (401) is first placed up side down, as shown in FIG. 7. Then a heating process is employed to melt the adhesive heat conductive agent (401) to allow the adhesive heat conductive agent (401) to flow out of the recesses (304) and eventually fill a gap between the heat dissipating fins (30) and the heat conductive tube (402). Thereafter, when the adhesive heat conductive agent (401) has cooled and hardened, the heat conductive tube (402) is securely connected to the heat dissipating fins (30). With reference to FIGS. 8 and 9, the third embodiment of the heat dissipating fin (50) of the present invention is configured to have a board (501), a through hole (502) defined through the board (501) and a ring (503) formed on and extending out from a periphery defining the through hole (502). The ring (503) has an annular groove (504) defined in an inner periphery of the ring (503) to function as the receiving space in this embodiment.

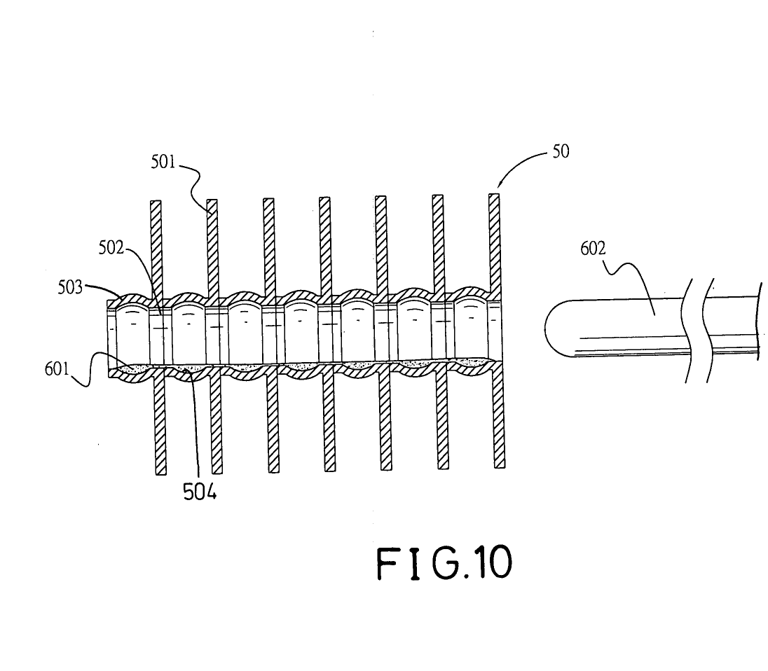

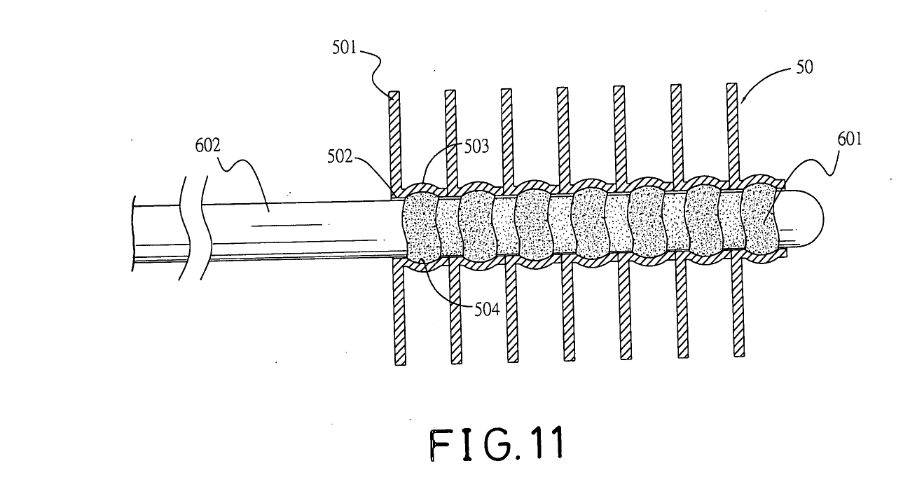

With reference to FIGS. 10 and 11, when the heat sink of the present invention is to be assembled, multiple heat dissipating fins (50) are joined together to allow the through holes (502) of the heat dissipating fins (50) to communicate with one another. Then an adhesive heat conductive agent (601) made of a material such as gold, silver or tin or the combination thereof is injected into the aligned through holes (502) to be received in one side of each of the annular grooves (304) before a heat conductive tube (602) is first extended into the aligned through holes (502) of the heat dissipating fins (50). With the extension of the heat conductive tube (602) into the through holes (502) of the heat dissipating fins (50), the combination of the heat conductive tube (602) and the heat dissipating fins (50) having therein the adhesive heat conductive agent (601) is first placed up side down. Then a heating process is employed to melt the adhesive heat conductive agent (601) to allow the adhesive heat conductive agent (601) to flow and eventually fill a gap between the heat dissipating fins (50) and the heat conductive tube (602). Thereafter, when the adhesive heat conductive agent (601) has cooled and hardened, the heat conductive tube (602) is securely connected to the heat dissipating fins (50).

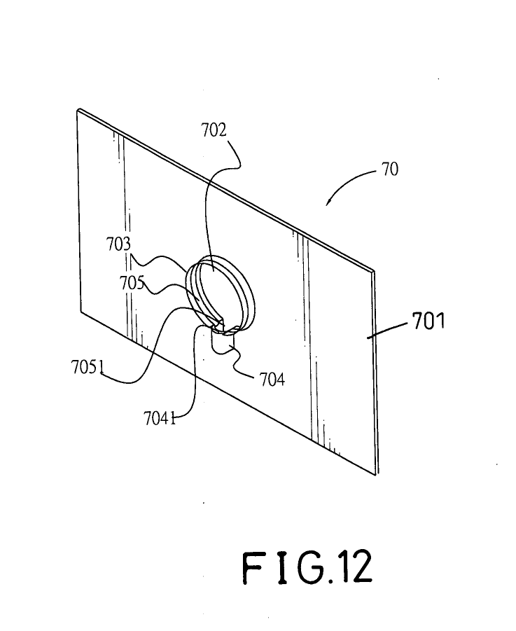

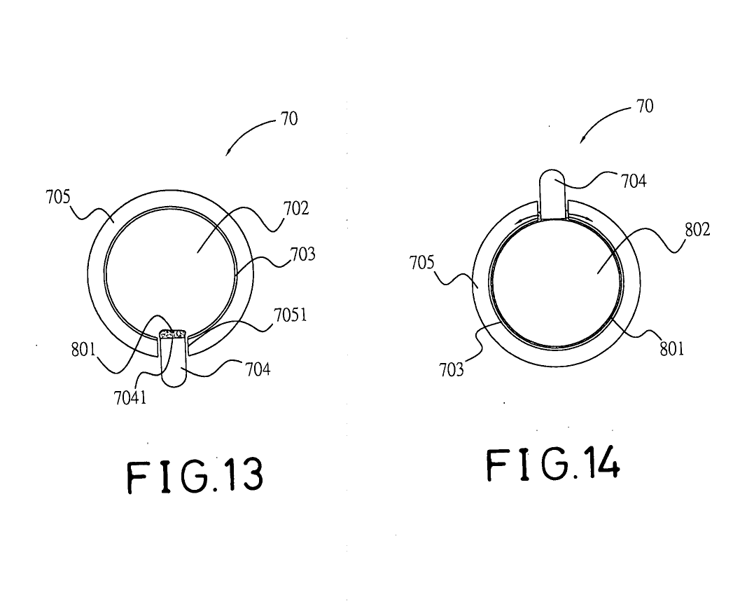

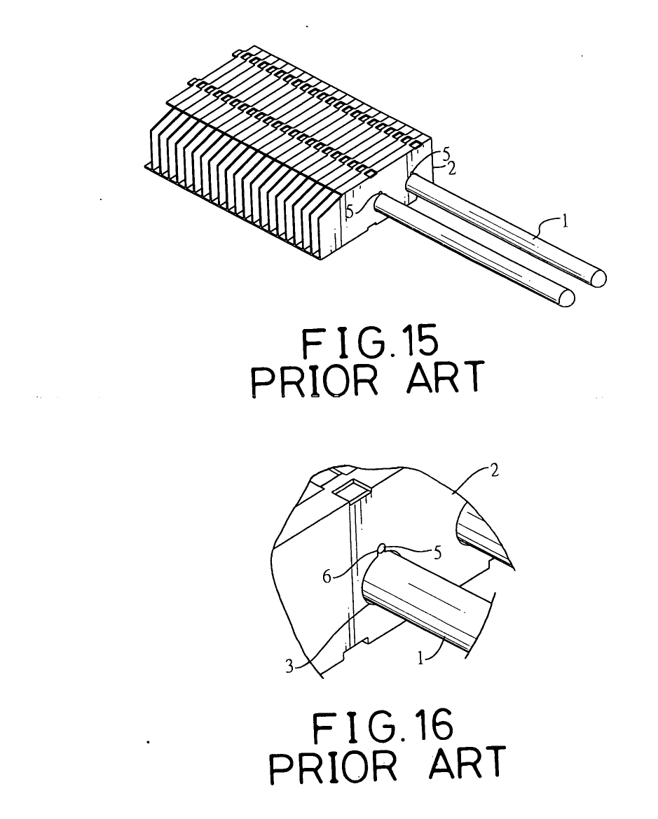

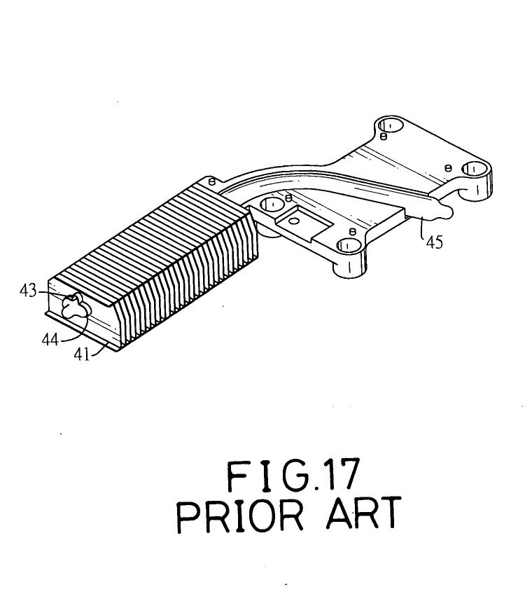

With reference to FIGS. 12, 13 and 14, the fourth embodiment of the heat dissipating fin (70) of the present invention includes a board (701), a through hole (702) defined through the board (701), a ring (703) formed on and extending out from a periphery defining the through hole (702) and a protrusion (704) attached to a side face of the board (701). The receiving space in this embodiment includes an annular groove (705) defined in an inner periphery of the ring (703) and an indentation (7041) defined in the protrusion (704) to communicate with an opening (7051) defined in the ring (703) and communicating with the through hole (702) and the annular groove (705).

When the heat sink of this embodiment of the present invention is to be assembled, multiple heat dissipating fins (70) are joined together to allow the through holes (702) of the heat dissipating fins (70) to align. Then an adhesive heat conductive agent (801) made of a material such as gold, silver or tin or the combination thereof is injected into the aligned through holes (702) to be received in each one of the indentations (7041) before a heat conductive tube (802) is extended into the aligned through holes (702) of the heat dissipating fins (70). With the extension of the heat conductive tube (802) into the through holes (702) of the heat dissipating fins (70), the combination of the heat conductive tube (802) and the heat dissipating fins (70) having therein the adhesive heat conductive agent (801) is first placed up side down. Then a heating process is employed to melt the adhesive heat conductive agent (801) to allow the adhesive heat conductive agent (601) to flow out of the indentations (7071) from the opening (7051) to the annular groove (705) and eventually fill a gap between the heat dissipating fins (70) and the heat conductive tube (802). Thereafter, when the adhesive heat conductive agent (801) has cooled and hardened, the heat conductive tube (802) is securely connected to the heat dissipating fins (70).

In summary, the present invention has the following advantages:

1. Before extending the heat conducting tube into the through holes of the heat dissipating fins, the adhesive heat conductive agent is first introduced into the through holes. Thus the operator has sufficient space to work and is able to control the flowing pattern of the adhesive heat conductive agent inside the through holes.

2. Due to the viscosity of the adhesive heat conductive agent, after the combination of the heat dissipating fins and the heat conductive tube is placed up side down to allow the adhesive heat conductive agent to gradually fill the gap between the heat dissipating fins and the heat conductive tube and eventually cover the outer periphery of the heat conductive tube, the engagement between the heat dissipating fins and the heat conductive tube is secured after the adhesive heat conductive agent has cooled and hardened.

3. The temperature of the heating process is low such that the integrity of the heat conductive tube is maintained.

4. Due to its features, the adhesive heat conductive agent is easy to store and applied to heat conductive tubes of different sizes.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for making a heat sink comprising the steps of:
arranging heat dissipating fins to align through holes of the heat dissipating fins;
applying an adhesive heat conductive agent to the through holes to allow the adhesive heat conductive agent to be received in a receiving space of each of the heat dissipating fins;
extending a heat conductive tube into the aligned through holes;
inverting and heating the heat dissipating fins as well as the heat conductive tube to allow the adhesive heat conductive agent to cover an outer periphery of the heat conductive tube and to fill a gap between the heat dissipating fins and the heat conductive tube; and
cooling the adhesive heat conductive agent so as to secure engagement between the heat dissipating fins and the heat conductive tube.

2. A heat sink constructed in accordance with the method as claimed in claim 1, the heat sink comprising:
heat dissipating fins securely connected to each other and each heat dissipating fin having a board, a through hole defined through the board, a receiving space formed on an attachment on a side face of the board to communicate with the through hole;
an adhesive heat conductive agent received in the receiving space; and
a heat conductive tube extending through aligned through holes of the heat dissipating fins, the adhesive heat conductive agent is so arranged in the receiving space that the adhesive heat conductive agent *covers an outer periphery of the heat conductive tube and thus engagement between the heat conductive tube and the heat dissipating fins is secured after the adhesive heat conductive agent has cooled and hardened.

3. The heat sink as claimed in claim 2, wherein the adhesive heat conductive agent is selected from a group consisting of gold, silver and tin or combination thereof.

4. The heat sink as claimed in claim 2, wherein the attachment is a protrusion formed on the side face of the board and the receiving space is an indentation defined in the attachment.

5. The heat sink as claimed in claim 3, wherein the attachment is a protrusion formed on the side face of the board and the receiving space is an indentation defined in the attachment.

6. The heat sink as claimed in claim 2, wherein the attachment is a ring formed on the side face of the board and the receiving space is a recess defined in the attachment.

7. The heat sink as claimed in claim 3, the attachment is a ring formed on the side face of the board and the receiving space is a recess defined in the attachment.

8. The heat sink as claimed in claim 2, wherein the attachment is a ring formed on the side face of the board and the receiving space is an annular groove defined in an inner periphery of the ring.

9. The heat sink as claimed in claim 3, wherein the attachment is a ring formed on the side face of the board and the receiving space is an annular groove defined in an inner periphery of the ring.

10. The heat sink as claimed in claim 2, wherein the attachment is composed of a protrusion and a ring respectively formed on the side face of the board, the protrusion has an indentation defined in the protrusion to communicate with the through hole and the ring has an annular groove defined in an inner periphery of the ring and an opening defined to communicate with the through hole so that the adhesive heat conductive agent is received in the indentations of the heat dissipating fins and flows to fill a gap between the heat conductive tube and the heat dissipating fins after the combination of the heat conductive tube and the heat dissipating fins is placed up side down and heated.

11. The heat sink as claimed in claim 3, wherein the attachment is composed of a protrusion and a ring respectively formed on the side face of the board, the protrusion has an indentation defined in the protrusion to communicate with the through hole and the ring has an annular groove defined in an inner periphery of the ring and an opening defined to communicate with the through hole so that the adhesive heat conductive agent is received in the indentations of the heat dissipating fins and flows to fill a gap between the heat conductive tube and the heat dissipating fins after the combination of the heat conductive tube and the heat dissipating fins is placed up side down.

12. The heat sink as claimed in claim 5, wherein the receiving space further has an annular groove defined in a ring formed on an inner periphery of the ring.

13. The heat sink as claimed in claim 9, wherein the receiving space further has an indentation defined in a protrusion formed on the side face of the board to communicate with the through hole.

14. A heat sink made in accordance with the method as claimed in claim 1, the heat sink comprising:
heat dissipating fins securely connected to each other and each heat dissipating fin having a board, a through hole defined through the board, a receiving space formed on an attachment on a side face of the board to communicate with the through hole;
an adhesive heat conductive agent received in the receiving space; and
a heat conductive tube extending through aligned through holes of the heat dissipating fins, the adhesive heat conductive agent is so arranged in the receiving space that the adhesive heat conductive agent covers an outer periphery of the heat conductive tube and thus engagement between the heat conductive tube and the heat dissipating fins is secured after the adhesive heat conductive agent has cooled and hardened,
wherein the attachment is a ring formed on the side face of the board and the receiving space is an annular groove defined in an inner periphery of the ring.

15. The heat sink as claimed in claim 14, wherein the adhesive heat conductive agent is selected from a group consisting of gold, silver and tin or combination thereof.
